(19) United States
(12) Patent Application Publication
(10) Pub. No.: US 2010/0233876 A1
(43) Pub. Date: Sep. 16, 2010

(54) FILM FORMING APPARATUS, FILM FORMING METHOD, COMPUTER PROGRAM AND STORAGE MEDIUM

(75) Inventors: Kenji Matsumoto, Yamanashi (JP); Junichi Koike, Miyagi (JP); Koji Neishi, Miyagi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignees: TOKYO ELECTRON LIMITED, Minato-ku (JP); NATIONAL UNIVERSITY CORPORATION TOHOKU UNIVERSITY, Sendai-shi (JP)

(21) Appl. No.: 12/303,831

(22) PCT Filed: Jun. 8, 2007
(86) PCT No.: PCT/JP2007/061637

§ 371 Date: Dec. 8, 2008

(30) Foreign Application Priority Data
Jun. 8, 2006 (JP) 2006-159942
Jun. 5, 2007 (JP) 2007-148856

(51) Int. Cl. H01L 21/768; C23C 16/458

(52) U.S. Cl. 438/652; 118/728; 257/E21.585

(57) ABSTRACT

In a film forming method, a substrate is first loaded into a vacuum-evacuable processing chamber. At least a transition metal-containing source gas and a reduction gas are supplied into the processing chamber, and the substrate is heated. Then, a thin film is formed in a recess in the surface of the substrate by heat treatment. Accordingly, the surface recess of the substrate can be filled with a copper film.

### FIELD OF THE INVENTION

The present invention relates to a film forming apparatus and a film forming method for forming, e.g., a copper-manganese (CuMn) alloy film or a manganese (Mn) film, as a seeding film, on a surface of a substrate to be processed such as a semiconductor wafer and the like.

### BACKGROUND OF THE INVENTION

In general, a desired semiconductor device is manufactured by repeatedly performing various processes such as a film forming process or a pattern etching process on a semiconductor wafer. With a demand for high integration and miniaturization of semiconductor devices, line widths or hole diameters are getting smaller. In addition, as a wiring material or a filling material for filling recesses such as trenches or holes, copper which has low electrical resistance and is inexpensive is being widely used in order to satisfy the need to reduce electrical resistance due to the miniaturization of various dimensions (Patent Document 1). When copper is used as the wiring material or filling material, a tantalum (Ta) metal film, a tantalum nitride (TaN) film or the like is generally used as a barrier layer to prevent copper from being diffused to the underlying layers.

Further, in order to fill the recesses, a thin seeding film made of copper is first formed on the entire surface of a wafer, including the entire inner surface of the recess, in a plasma sputtering apparatus. Then, a copper plating process is performed on the entire wafer surface, thereby completely filling the recesses. Following this, an excess copper film on the wafer surface is removed by a polishing process such as a CMP (chemical mechanical polishing) process.

The above-described recess filling process will be described with reference to FIG. 7. FIG. 7 shows a general process for filling a recess of a semiconductor wafer. On the surface of an insulating layer 1, e.g., an interlayer insulation film and the like, formed on the semiconductor wafer W, a recess 2 such as a via hole, a through hole, a groove (a trench or dual damascene structure) or the like is formed. At the bottom of the recess 2, an underlying wiring layer 3 made of, e.g., copper, is formed to be exposed. Due to the miniaturization of design rules, the recess 2 has a very small width or inner diameter of, e.g., about 120 nm, and an aspect ratio of, e.g., about 2 to 4. The depiction of a diffusion barrier film and an etching stop film are simplified or omitted in FIG. 7.

A barrier layer 4 having, e.g., a laminated structure of a TaN film and a Ta film, has been substantially uniformly formed on the surface of the semiconductor wafer W including the inner surface of the recess 2 in a plasma sputtering apparatus (see FIG. 7A). Then, in the plasma sputtering apparatus, a seeding film 6 formed of a thin copper film, as a metal film, is formed on the entire surface of the wafer including the inner surface of the recess 2 (see FIG. 7B). When the seeding film 6 is formed in the plasma sputter apparatus, a high frequency bias power is applied to the semiconductor wafer side to efficiently introduce copper ions. Then, a copper plating process is performed on the wafer surface, so that the recess 2 is filled with a metal film 8, i.e., a copper film (see FIG. 7C). Then, excess metal film 8, seeding film 6 and barrier layer 4 on the wafer surface are removed by a polishing process such as the CMP process.

Recently, various developments have been made in order to further improve the reliability of the barrier layer, and among them, a self-forming barrier layer including a Mn film and/or a CuMn alloy film in place of said Ta film and/or TaN film has drawn (Patent Document 2). The Mn film and/or CuMn alloy film is formed by sputtering, and the Mn film and/or CuMn alloy film itself serves as a seeding film so that a Cu plating layer can be formed directly thereon. Further, since the film is annealed after the formation thereof, it reacts with the underlying insulation film, i.e., SiO₂ layer, in a self-aligned manner, whereby a barrier film called a MnSixOy (x, y: any integers) film is formed at the interface portion between the SiO₂ layer and the Mn film and/or CuMn alloy film. Therefore, it is possible to reduce the number of production processes.

Furthermore, when the Cu film is formed by, for example, the CVD method, Mn in the Mn film and/or CuMn film preferentially binds to halogen atoms received in the Cu film to trap the halogen atoms from the Cu film, thereby improving the quality of the Cu film wiring and, thus, obtaining the reliability of the wiring.

(Patent Document 1) Japanese Patent Laid-Open Application No. 2004-107747

(Patent Document 2) Japanese Patent Laid-Open Application No. 2005-277390

However, although the CuMn Alloy can be formed only by the sputtering method at the current technical level, the sputtering method cannot sufficiently cope with ultrafine patterns that are expected in the future, e.g., trenches or holes having a line width or hole diameter of less than 32 nm. Therefore, step coverage properties are deteriorated, so that the filling of the recesses can be insufficient.

Further, as described above, in the process of forming the seeding film 6, the plating process and the annealing process, different apparatuses corresponding to the respective processes, for example, a sputtering apparatus, an electrolytic plating apparatus and an annealing apparatus, are necessarily used. Thus, there is a problem in that apparatus expenses (equipment expenses) are increased.

Furthermore, the process of forming the seeding film 6 and the filling process cannot be performed insitu. For this reason, when the semiconductor wafer is delivered to a filling apparatus after forming the seeding film 6, the semiconductor wafer passes through an atmosphere of clean air. Thus, there are problems in that the highly reactive CuMn alloy film is oxidized and, as a result, the film formation of filled copper is deteriorated or Mn oxide formed by the oxidation of the Mn component of the seeding film increases contact resistance.

Further, in the process of the film formation by sputtering, the seeding film is formed to be thicker on the bottom of the recess than on the sidewall of the recess. For this reason, there is a problem in that, even though a appropriately thin MnSixOy film is formed on the sidewall of the recess by an annealing process, manganese or its oxides, having resistance higher than that of copper, remain on the bottom in large amounts, leading to a significant increase in contact resistance.

### SUMMARY OF THE INVENTION

The present invention has paid attention to the above-described problems and has been devised in order to effectively solve these problems. It is an object of the present invention to provide a film forming method, a film forming apparatus, a computer program and a storage medium, which allow even a fine recess to be filled with high step coverage by forming, for example, a CuMn alloy film or a Mn film, by heat treatment such as CVD, and which allow continuous processes to be performed in a same processing apparatus, thus greatly reducing apparatus expenses.

In accordance with the present invention there is provided a film forming method includes: loading a substrate to be processed into a vacuum-evacuable processing chamber; and supplying at least a transition metal-containing source gas and a reduction gas into the processing chamber, while heating the substrate, thereby forming a thin film on a surface of the substrate by heat treatment.

In the vacuum-evacuable processing chamber, the thin film is formed on the substrate surface by heat treatment by using a transition metal-containing source gas and a reduction gas. Therefore, even a fine recess can be filled with high step coverage, and continuous processes can be performed in the same processing apparatus, thus greatly reducing apparatus expenses.

The present invention is about the film forming method wherein a copper-containing source gas, the transition metal-containing source gas and the reduction gas are supplied into the processing chamber, while the substrate is heated, thereby forming a thin film on the substrate surface by heat treatment.

As described above, in the processing chamber, the thin film is formed on the surface of the substrate by heat treatment using the copper-containing source gas, the transition metal-containing source gas and the reduction gas. Thus, even a fine recess can be filled with high step coverage, and continuous processes can be performed in the same processing apparatus, thus greatly reducing apparatus expenses.

In accordance with the present invention the heat treatment is a chemical vapor deposition (CVD) method.

In accordance with the present invention, the heat treatment is an atomic layer deposition (ALD) method in which film formation is performed by alternately and repeatedly supplying the source gases and the reduction gas. In accordance with the present invention the heat treatment is performed by alternately and repeatedly supplying the two source gases with an intermittent period therebetween and supplying the reduction gas during the intermittent period.

In accordance with the present invention, a filling of a recess formed in the substrate is performed by depositing a copper film by a CVD method on the substrate formed with the thin film thereon.

In accordance with the present invention, the filling is performed in the processing chamber in which the thin film has been formed.

In accordance with the aspect of the present invention, since continuous processes can be performed in the same apparatus, that is, insitu, the formation of an unnecessary metal oxide film can be suppressed. As a result, filling properties can be improved and, while preventing contact resistance from being increased.

In accordance with the present invention, an annealing process is performed on the substrate, after the filling is performed.

In accordance with the present invention, the annealing process is performed in the processing chamber in which the formation of the thin film has been performed.

In accordance with the present invention, the filling of a recess of the substrate is performed by depositing a copper film by a plating method on the substrate formed with the thin film thereon.

In accordance with the present invention, an annealing process is performed on the substrate, after the filling of the recess in the substrate is performed.

In accordance with the present invention, the amount of the copper-containing source gas and/or the transition metal-containing source gas supplied are changed during the heat treatment in order to change a composition ratio between copper and transition metal in the thin film, in the thickness direction of the thin film.

In accordance with the present invention, the amount of each of the source gases supplied is controlled so that the composition ratio of the transition metal in the thin film is high at the lower layer side of the thin film and decreases toward the upper layer side of the thin film.

In accordance with the present invention, an amount of the transition metal contained in the thin film is in a range from 0.7 to 2.6 mm, when converted into a film thickness of the pure transition metal contained in the thin film.

In accordance with the present invention, the substrate surface is made of an underlying film of the thin film, the underlying film being made of at least one film selected from a group formed of a SiO₂ film, a SiOC film, a SiCOH film, a SiCN film, a porous silica film, a porous methylsilsesquioxane film, a polyarylene film, a SiLK (registered trademark name) film and a fluorocarbon film.

In accordance with the present invention, a source material of the transition metal-containing source gas is formed of an organometallic material or a metal complex material.

In accordance with the present invention, the organometallic material is M(R-Cp)x (x: natural number), wherein M represents a transition metal, R represents an alkyl group and is one selected from a group formed of H, CH₃, C₂H₅, C₃H₇ and C₄H₉, and Cp is a cyclopentadienyl group (C₅H₄).

In accordance with the present invention, the organometallic material is M(R-Cp)x(CO)y (x and y: natural numbers), wherein M represents a transition metal, R represents an alkyl group and is one selected from a group formed of H, CH₃, C₂H₅, C₃H₇ and C₄H₉, Cp is a cyclopentadienyl group (C₅H₄), and CO is a carbonyl group.

In accordance with the present invention, the organometallic metal includes a transition metal, C and H.

In accordance with the present invention, the transition metal is at least one metal selected from a group formed of Mn, Nb, Zr, Cr, V, Y, Pd, Ni, Pt, Rh, Tc, Al, Mg, Sn, Ge, Ti and Re.

In accordance with the present invention, wherein the transition metal is formed of manganese (Mn), and the corresponding organometallic material containing manganese is at least one material selected from a group formed of Cp₂Mn[═Mn(C₅H₅)₂], (MeCp)₂Mn[═Mn (CH₃C₅H₄)₂], (EtCp)₂Mn [═Mn(C₂H₅C₅H₄)₂], (i-PrCp)₂Mn [═Mn(C₃H₇C₅H₄)₂], MeCpMn(CO)₃[═(CH₃C₅H₄)Mn(CO)₃], (t-BuCp)₂Mn [═Mn (C₄H₉C₅H₄)₂], CH₃Mn(CO)₅, Mn(DPM)₃[═Mn(C₁₁H₁₉O₂)₃], Mn(DMPD)(EtCp)[═Mn(C₇H₁₁C₂H₅C₅H₄)], Mn(acac)₂[═Mn (C₅H₇O₂)₂], Mn(DPM)₂[═Mn(C₁₁H₁₉O₂)₂], Mn(acac)₃[═Mn(C₅H₇O₂)₃] and Mn(hfac)₂[═Mn(C₅HF₆O₂)₃].

In accordance with the present invention, the film forming method wherein a plasma is used in the heat treatment.

In accordance with the present invention, the source gases and the reduction gas are mixed with each other in the processing chamber.

In accordance with the present invention, the reduction gas is H₂ gas.

In accordance with the present invention, there is provided a film forming apparatus for forming a transition metal-containing thin film on a surface of a substrate to be processed by heat treatment.

The apparatus includes: a vacuum-evacuable processing chamber; a mounting table structure provided in the processing chamber for mounting thereon the substrate; a heating unit for heating the substrate; a gas introducing unit for introducing a gas into the processing chamber; a source gas supply unit for supplying one or more source gases into the gas introducing unit; and a reduction gas supply unit for supplying a reduction gas into the gas introducing unit.

In accordance with the present invention, the number of the source gases is greater than one and the source gas supply unit has different source material branch lines provided respectively for the source gases, wherein the source gas branch lines join together before reaching the gas introducing unit.

In accordance with the present invention, the number of the source gases is greater than one, and the source gas supply unit has different source material branch lines respectively provided for the source gases, the source gas branch lines being commonly connected to the gas introducing unit without joining together.

In accordance with the present invention, the source gas branch lines are provided with a line heating unit for heating in order to prevent liquefaction of the source gases flowing through the respective source gas branch lines.

In accordance with the present invention, the source gas at least includes a transition metal-containing source gas.

In accordance with the present invention, the source gas includes a copper-containing source material and a transition metal-containing source gas.

In accordance with the present invention, the reduction gas is H₂ gas.

In accordance with the present invention, there is provided a computer executable-program which is used in a film forming apparatus to execute a film forming method in a computer, the film forming method including: loading a substrate to be processed into a vacuum-evacuable processing chamber; and supplying at least a transition metal-containing source gas and a reduction gas into the processing chamber, while heating the substrate, thereby forming a thin film on the substrate surface by heat treatment.

In accordance with the present invention, A computer executable-program for executing a method of forming a transition metal-containing thin film on a substrate to be processed by heat treatment by using a film forming apparatus, the film forming apparatus including: a vacuum-evacuable processing chamber; a mounting table structure provided in the processing chamber for mounting thereon the substrate; a heating unit for heating the substrate; a gas introducing unit for introducing a gas into the processing chamber; a source gas supply unit for supplying one or more source gases into the gas introducing unit; a reduction gas supply unit for supplying a reduction gas into the gas introducing unit; and a control unit for controlling all the units of the apparatus.

The film forming method includes: loading the substrate into the vacuum-evacuable processing chamber; and supplying at least a transition metal-containing source gas and the reduction gas into the processing chamber, while heating the substrate, thereby forming a thin film on the substrate surface by the heat treatment.

The source gases include a copper-containing source gas and the transition metal-containing source gas.

In accordance with the present invention, a computer-readable storage medium storing therein a computer-executable program which is used in a film forming apparatus to execute a film forming method in a computer. The film forming method includes: loading a substrate to be processed into a vacuum-evacuable processing chamber; and supplying at least a transition metal-containing source gas and a reduction gas into the processing chamber, while heating the substrate, thereby forming a thin film on the substrate surface by heat treatment.

In accordance with the present invention, A computer-readable storage medium storing a computer-executable program for executing a method of forming a transition metal-containing thin film on a substrate by heat treatment by using a film forming apparatus.

The film forming apparatus includes: a vacuum-evacuable processing chamber; a mounting table structure provided in the processing chamber for mounting thereon the substrate; a heating unit for heating the substrate; a gas introducing unit for introducing a gas into the processing chamber; a source gas supply unit for supplying one or more source gases into the gas introducing unit; a reduction gas supply unit for supplying a reduction gas into the gas introducing unit; and a control unit for controlling all the units of the apparatus.

The film forming method includes: loading the substrate into the vacuum-evacuable processing chamber; and supplying at least a transition metal-containing source gas and the reduction gas into the processing chamber, while heating the substrate, thereby forming a thin film on the substrate surface by the heat treatment. The source gases include a copper-containing source gas and the transition metal-containing source gas.

As described above, the film forming method and film forming apparatus in accordance with the present invention can achieve excellent effects as follows.

In the vacuum-evacuable processing, the thin film is formed on the substrate surface by heat treatment by supplying the copper-containing source gas, the transition metal-containing source gas and the reduction gas into the processing chamber. Therefore, even a fine recess can be filled with high step coverage, and continuous processes can be performed in the same processing apparatus, thus greatly reducing apparatus expenses.

Further, in the vacuum-evacuable processing chamber, the thin film is formed on the substrate surface by heat treatment by using the transition metal-containing source gas and the reduction gas. Accordingly, even a fine recess can be filled with high step coverage, and continuous processes can be performed in the same processing apparatus, thus greatly reducing apparatus expenses.

In addition, in accordance with the present invention, because continuous processes can be performed in the same apparatus, that is, insitu, the formation of unnecessary metal oxide films can be suppressed. As a result, filling properties can be improved and, while contact resistance is prevented from being increased. Furthermore, it is possible to improve the reliability of semiconductor devices and increase the yield of semiconductor devices.

In accordance with the present invention, the supplied amount of each source gas changes during the heat treatment process, so that the composition ratio between copper and transition metal in the thin film changes in the thickness direction of the thin film. Thus, the adhesion of the thin film to the underlying film can be improved.

In addition, in accordance with the present invention, the amount of the transition metal contained in the thin film can be optimized, and the film properties of the copper wiring can be prevented from deteriorating due to an excessive amount of the transition metal.

### BRIEF DESCRIPTION OF THE DRAWINGS

FIG. 1 is a configuration view showing one example of a film forming apparatus in accordance with the present invention.

FIGS. 2A to 2D show the state of deposition of a thin film in each process with respect to a recess in a semiconductor.

FIGS. 3A and 3B are flow charts showing each step of a film forming method in accordance with the present invention.

FIGS. 4A to 4C are timing views explaining the state of supply of each gas in an ALD process during the formation of a seeding film.

FIG. 5 graphically shows examples of the changes in the supplied amounts of a Mn-containing source gas and a Cu-containing source gas as a function of film formation time.

FIG. 6 is a partial configuration view showing a modified embodiment of a gas supply unit in a film forming apparatus.

FIGS. 7A to 7C show a general process for filling a recess in a semiconductor wafer.

### DETAILED DESCRIPTION OF THE EMBODIMENTS

Hereinafter, the embodiments of a film forming method and film forming apparatus in accordance with the present invention will be described in detail with reference to the accompanying drawings.

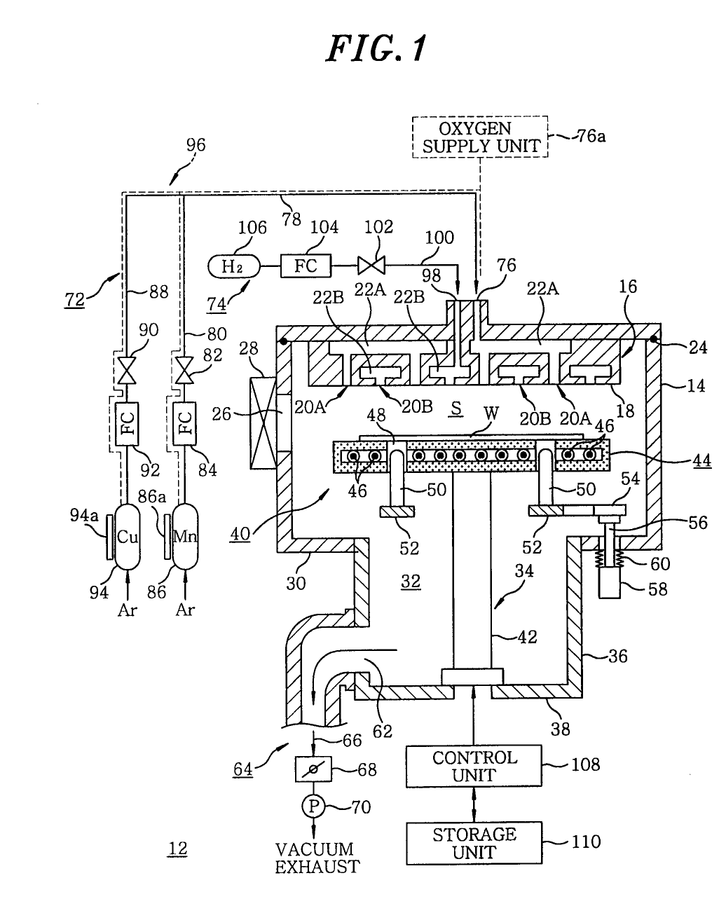

FIG. 1 is a configuration view showing one example of a film forming apparatus in accordance with the embodiments of the present invention. As shown therein, a film forming apparatus 12 in accordance with the embodiment of the present invention has a processing chamber 14 made of aluminum having a circular inner cross section. The sidewall of the processing chamber 14 is provided with a chamber heating unit (not shown) such as a heater rod for heating the chamber. The ceiling portion of the processing chamber 14 is provided with a shower head 16 that is a gas introducing unit for introducing a processing gas, e.g., a film forming gas. The shower head 16 has a gas injection surface 18 at the bottom surface thereof, and the processing gas is injected toward a processing space S from a plurality of gas injection holes 20a and 20b provided at the gas injection surface 18.

The shower head 16 includes two partitioned hollow gas diffusion spaces 22a and 22b communicating with the gas diffusion holes 20a and 20b. The processing gases introduced into the gas diffusion chambers 22a and 22b are diffused in a planar direction, and then injected from the respective gas diffusion holes 20a and 20b communicating with the respective gas diffusion chambers 22a and 22b. In this case, the gas diffusion holes 20a and 20b are arranged in a matrix shape, the gases injected from the respective gas injection holes 20a and 20b are mixed with each other in the processing space S.

Such a gas supply form is designated “post mix”. The shower head 16 is entirely formed of, for example, nickel, a nickel alloy such as Hastelloy (registered trademark name) and the like, aluminum or an aluminum alloy. If a film formation is carried out by an ALD method as described later, the shower head 16 may also have one gas diffusion chamber. A seal member 24 formed of, e.g., an O-ring, is provided at the junction between the shower head 16 and an opening provided at the upper end of the processing chamber 14, so that the processing unit 14 can be airtightly maintained.

Moreover, provided at the sidewall of the processing chamber 14 is a loading/unloading port 26 for transferring a semiconductor wafer W in and out of the processing chamber 14. On the loading unloading 26, a gate valve 28 for airtightly opening and closing the loading/unloading port 25 is provided.

Further, at the bottom portion 30 of the processing chamber 14, an exhaust space 32 is formed. Specifically, at the central portion of the chamber bottom portion 30, a large opening 34 is formed, and a cylindrical partition wall 36 extending downward is connected to the opening 34 to thereby form the exhaust space 32 within the partition wall 36. At the bottom portion 38 of the cylindrical partition wall 36 defining the exhaust space 32, a mounting table structure 40 that stands up therefrom is provided. The mounting table structure 40 includes a cylindrical support 42 standing up from the bottom 38, and a mounting table 44 fixed on the top of the support 42 and mounting thereon a semiconductor wafer W to be processed.

Further, the mounting table 44 is made of, e.g., ceramic material or quartz glass. In the mounting table 44, a resistance heater 46 such as a carbon wire heater or the like, that generates a heat by electric conductance, is provided to heat the semiconductor wafer W mounted on the mounting table 44.

In the mounting table 44, a plurality (for example, three) of pin insertion through holes 48 that penetrate the mounting table 44 in the vertical direction are formed (only two pin insertion through holes 48 are shown in FIG. 1). In each of the pin insertion through holes 48, an upthrust pin is inserted loosely so that it is movable upward and downward. At the lower end of the upthrust pin 50, a circular ring-shaped upthrust ring 52 made of, e.g., a ceramic material such as alumina, is disposed. The lower end of the upthrust pin 50 is supported by the uptrhust ring 52 in a non-fixed state. An arm unit 54 extending from the upthrust ring 52 is connected to a up/down rod 56 that passes through the chamber bottom portion 30. The up/down rod 56 is movable upward and downward by an actuator 58. Accordingly, when the wafer W is loaded or unloaded, each of the upthrust pins 50 is lifted upward from the top of each of the pin insertion through holes 48. In the through portion of the chamber bottom in which the up/down rod 56 of the actuator 58 is placed, an extensible and contractible bellows 60 is provided, so that the up/down rod 56 can move upward and downward while maintaining the airtightness of the processing chamber 14.

An opening 34 at the inlet side of the exhaust space 32 is formed smaller than the diameter of the mounting table 44, and the processing gases that flow downward through a space formed around the outer periphery of the mounting table 44 enter below the mounting table 44 and flow into the opening 34. At the lower sidewall of the cylindrical partition wall 36, an exhaust opening 62 facing the exhaust space 32 is formed. To the exhaust opening 62, a vacuum exhaust system 64 is connected. The vacuum exhaust system has an exhaust passage 66 connected to the exhaust opening 62, and in the exhaust passage 66, a pressure control valve 68, a vacuum pump 70 and the like are sequentially provided, so that they can vacuum-exhaust the internal atmosphere of the processing chamber 14 and the exhaust space 32 while controlling the pressure.

In order to supply specific gases to the shower head 16, a source gas supply unit 72 for supplying source gas and a reduction gas supply unit 74 for supplying reduction gas are connected to the shower head 16. Specifically, the source gas supply unit 72 has a source gas line 78 connected to a gas inlet 76 for one gas diffusion chamber 22a of the two gas diffusion chambers. The source gas line 78 is branched into two lines, and one branch line 80 of them sequentially includes an opening/closing valve 82 and a flow controller 84 such as a mass flow controller and is connected to a first source material supply source 86 receiving therein a first source material.

As the first source material, a transition metal-containing source material is used. For example, the source material can be gasified by bubbling it with an inert gas such as a flow-controlled Ar gas, and thus the transition metal-containing source gas can be carried and supplied by the inert gas. If the vapor pressure of the source material is low, the first source material supply source 86 is heated with a heater 86a in order to increase the vapor pressure thereof. For example, a (MeCp)₂Mn precursor containing manganese may be used as the transition metal-containing source material.

Further, the supply of the source gas may be performed not only by bubbling, but also by liquid source material vaporization or solution source material vaporization. As used herein, the term “liquid source material vaporization” refers to a process in which a source material that is a liquid at room temperature is vaporized in a vaporizer, and the term “solution source material vaporization” refers to a process in which a source material that is a solid or a liquid at room temperature is dissolved in a solvent to form a solution, and the solution is vaporized in a vaporizer. Such processes may be applied not only to the supply of the Mn-containing source gas, but also to a supply of a Cu-containing source gas.

Another branch line 88 sequentially includes an opening/closing valve 90 and a flow controller 92 such as a mass flow controller and is connected to a second source material supply source 94 receiving therein a second source material. As the second source material, a copper-containing source material is used. For example, the source material can be gasified by bubbling it with an inert gas such as flow-controlled Ar gas, and thus the copper-containing source gas can be carried and supplied by the inert gas. If the vapor pressure of the source material is low, the second source material supply source 94 is heated with a heater 94a in order to increase the vapor pressure thereof. For example, a precursor of Cu(hfac)TMVS, Cu(hfac)₂, Cu(dibm)₂ or the like, which contain copper, may be used as the copper-containing source material.

Moreover, as the inert gas for bubbling, He, Ne or the like may also be used instead of Ar gas.

Furthermore, the branch lines 80 and 88, the opening/closing valves 82 and 90 and the flow controllers 84 and 92, which are included in the branch lines, and the source gas line 78, are wound with a tape heater to heat them, thereby preventing them from being re-liquefied. Also, the source gas supply unit may be provided in a plurality depending on the source materials used.

The reduction gas supply unit 74 has a reduction gas line 100 connected to a gas inlet 98 for the other gas diffusion chamber 22B. The reduction gas line 100 sequentially includes an opening/closing valve 102 and a flow controller 104 such as a mass flow controller and is connected to a reduction gas supply source 106 receiving therein a reduction gas. As the reduction gas, H₂ gas is used herein, however, H₂O or a vaporized organic solvent may also be used.

Herein, the source gas is connected to the gas diffusion chamber 22A located at the upper side in the shower head 16, and the reduction gas is connected to the gas diffusion chamber 22B located at the lower side in the shower head 16. This is because the shower head 16 closely faces the mounting table 44, and thus the temperature of the gas injection surface 18 has a tendency to increase, and for this reason, if the source gas is introduced into the gas diffusion chamber 22b at the lower side in the shower head 16, the gas can be decomposed.

Further, although not shown, a unit for supplying a purge inert gas is connected to the shower head 16, so that purge gas is supplied, if necessary. As the purge gas, an inert gases such as N₂, Ar, He, Ne or the like may be used.

In addition, in order to control the entire operation of such apparatus, a control unit 108 including, for example, a microcomputer and the like, is provided so that it controls the start/stop of supplying each gas, the amount of each gas supplied, the internal pressure of the processing chamber 14, the temperature of the wafer W and the like. Further, the control unit 108 has a storage medium 110 storing therein a computer program for executing the above control operations. As the storage medium 110, e.g., a flexible disc, flash memory, a hard disc, a compact disc (CD) and the like may be used.

Hereinafter, the operation of the film forming apparatus configured as described above will be described.

First, a semiconductor wafer W to be processed maintained on a transfer arm (not shown) is loaded into the processing chamber 14 via the opened gate valve 28 and loading/unloading opening 26. The wafer is received on the upthrust pins 50 moved upward, and then mounted on the mounting table 50 by moving the upthrust pins 50 downward.

Then, the source gas supply unit 72 and/or the reduction gas supply unit 74 are/is operated to supply each of gases such as a film forming gas and the like as processing gases into the shower head 16 while controlling the flow rates thereof. The gases are injected from the gas injection holes 20a and 20b and introduced into the processing space S. The supply of the gases is carried out in various forms as described later. By continually driving the vacuum pump 70 provided in the vacuum exhaust system 64, the internal atmosphere of the processing chamber 14 and/or the exhaust space 32 is vacuum-exhausted, and the atmosphere of the processing space S is maintained at a specific processing pressure. Herein, the temperature of the wafer W is maintained at a specific processing temperature by heating with the resistance heater 46 provided in the mounting table 44. Accordingly, a desired thin film is formed on the surface of the semiconductor wafer W by heat treatment such as a thermal CVD method.

When the Cu-containing source gas and the Mn-containing source gas are introduced into the shower head 16, the gas line 78 and the branch lines 80 and 88 are heated by the line heating unit 96 to prevent the source gas flowing therethrough from being re-liquefied. Herein, the heating temperature varies depending on the source materials used, and if Cu(hfac)TMVS and (MeCp)₂Mn are used as the source gases, the gases are heated to a temperature at which they are not liquefied or thermally decomposed, for example, in a range from about 55 to 90° C. Further, the shower head 16 and the processing unit 14 are previously heated to a temperature in a range from about 60 to 80° C.

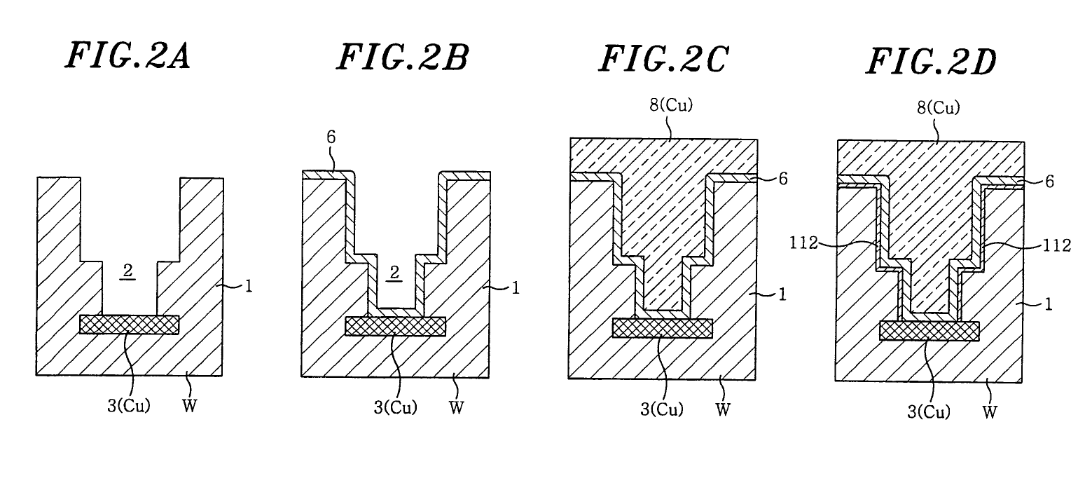

Hereinafter, a film forming method in accordance with the embodiments of the present invention will be described in detail with reference to FIGS. 2 to 4.

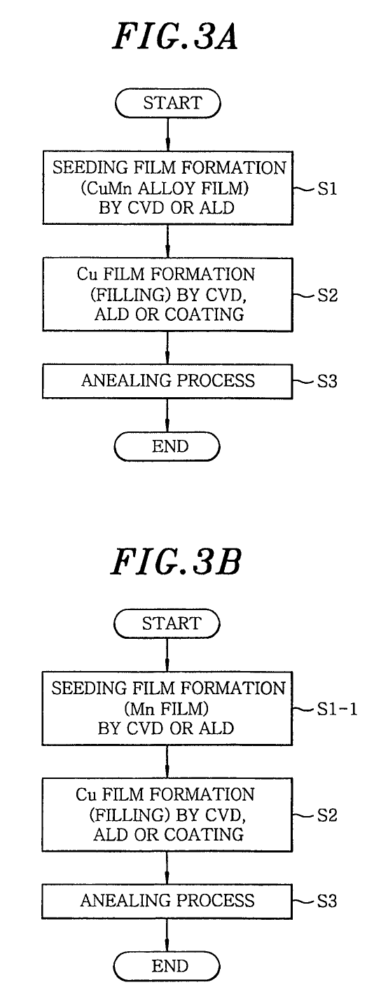

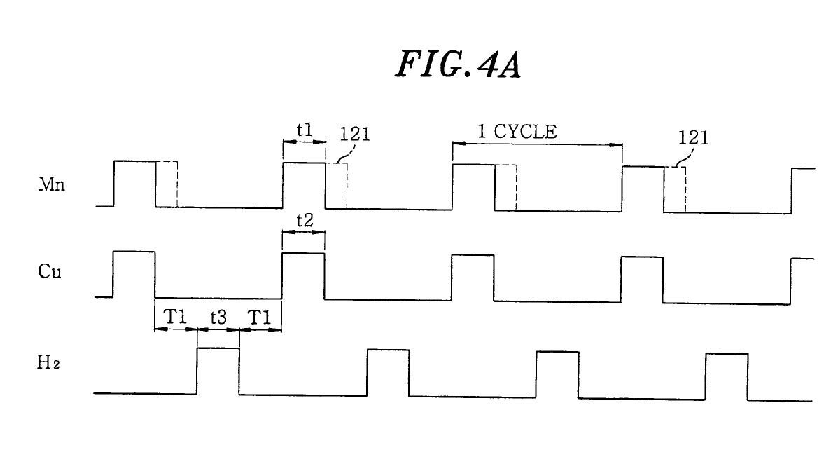

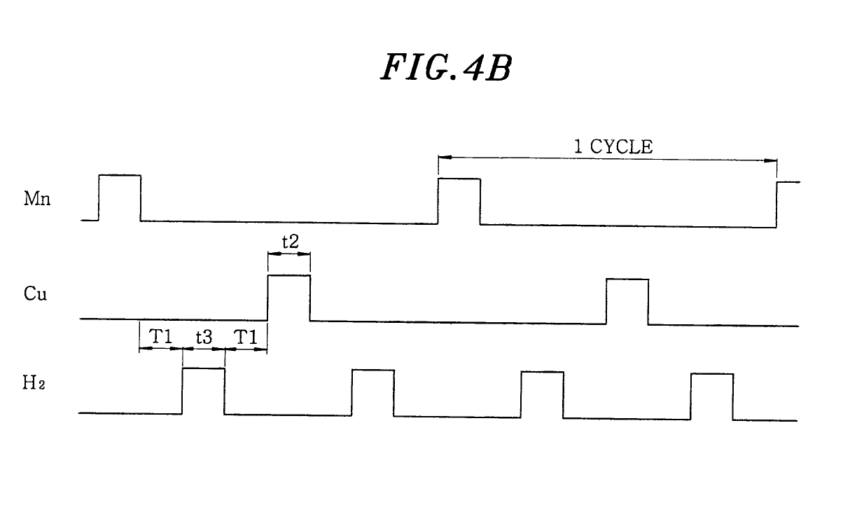

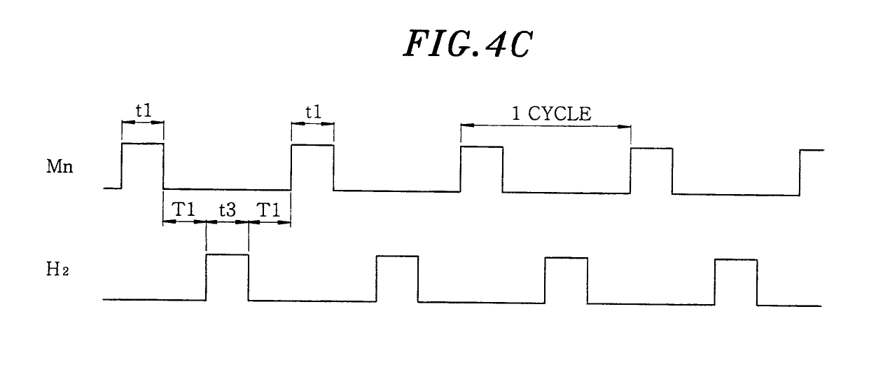

FIG. 2 shows a deposition state of a thin film in each step with respect to a recess in a semiconductor wafer, and FIG. 3 is a flowchart showing steps of the film forming method in accordance with the embodiments of the present invention. FIG. 3A shows a first embodiment, and FIG. 3B shows a second embodiment. FIG. 4 is a timing view showing the supply state of each gas during a seeding film formation by using ALD method.

An object of the present invention is to continuously execute a film forming process and an annealing process in one film forming apparatus insitu. For example, before the wafer W is carried into the film forming apparatus 12, as shown in FIG. 2A, a recess 2 such as a trench or a hole is formed in the surface of an insulating layer 1 such as an interlayer insulation film, formed on the wafer W, and an underlying wiring layer 3 made of copper or the like is exposed at the bottom of the recess 2. The insulating layer 1 to be an underlying film is made of silicon dioxide, SiO₂.

In the method of the embodiments of the present invention, as shown in FIG. 2B, a seeding film 6 is formed on the surface of the semiconductor wafer W in a seeding film forming step. In this case, the seeding film 6 may be a CuMn alloy film (S1 in FIG. 3A) or a Mn film (S1-1 in FIG. 3B). In addition, the formation of the seeding film 6 may be performed by using a CVD method or an ALD method. Herein, the term “ALD method” refers to a film forming method in which a thin film of an atomic level or molecular level is repeatedly formed by alternately supplying different film forming gases.

Then, as shown in FIG. 2C, a Cu film 8 as a metal film is formed in a filling step to fill the inside of the recess (S2 in FIGS. 3A and 3B). This filling step may be carried out by using a CVD method or an ALD method. Further, a PVD method (sputtering or vapor deposition) or a plating method may also be used in the same manner as in the prior art. If necessary, in order to surely form a barrier film, an annealing process is carried out by exposing the wafer W to high temperature, and thus, as shown in FIG. 2D, the seeding film 6 and the underlying insulating layer made of a SiO₂ film react in a self-aligned manner to form a barrier layer 112 formed of a MnSixOy (x and y: any integers) at the interface therebetween (S3 in FIGS. 3A and 3B). The annealing process may not be carried out if the barrier layer 112 is already formed in previous processes accompanying high-temperature processing. However, it is preferable to carry out the annealing process in order to ensure the formation of the barrier film 112.

Each step of the film forming method in accordance with the embodiments of the present invention will now be described in detail.

First, when the CuMn alloy film (S1 in FIG. 3A) as the seeding film 6 is formed, three kinds of film forming methods can be used. The first film forming method is simultaneously introducing all the Cu-containing source gas, the Mn-containing source gas and H₂ gas as the reduction gas and forming the CuMn alloy film by the CVD method.

In the second film forming method, the ALD method of FIG. 4A is used. That is, the Cu-containing source gas and the Mn-containing source gas are supplied in a synchronized manner, and these source gases and the H₂ gas are introduced in an alternate, intermittent and repeated manner. The intermittent period T1 between the introduction of the two source gases and the H₂ gas is a purge period, and the remaining gases in the processing chamber 14 may be exhausted by vacuum exhaust alone or by vacuum exhaust together with the introduction of an inert gas such as N₂ gas. The purge method may also be applied to a method described later.

In the ALD method, the period between, for example, a supply of Mn-containing source gas and its next supply of Mn-containing source gas, is one cycle, and during this cycle, a one-layer CuMn alloy film having a very small thickness, e.g., a thickness in a range from about 0.4 to 0.6 nm, is formed. Herein, the necessary thickness of the seeding film 6 is about 2 nm when converted into the film thickness of pure Mn metal contained in the CuMn film, and the film forming process is carried out for, for example, about 10 to 100 cycles. That is, if film formation is carried out by the ALD method, the controllability of the film thickness can be increased, and thus it is possible to form a thinner film with good controllability compared to the CVD method.

Herein, the process conditions (including those in CVD treatment) are as follows: a processing temperature in a range from about 70 to 450° C., a processing pressure in a range from about 1 Pa to 13 kPa, a flow rate of Mn-containing source gas in a range from about 0.1 to 10 sccm, and flow rate of Cu-containing source gas in a range from about 1 to 100 sccm. In any case, the amount of Cu is about 10-fold larger than that of Mn, so that the components of the CuMn alloy film are rich in Cu. The flow rate of the H₂ gas is in a range from about 5 to 500 sccm. However, because Cu has weak adhesion to an insulation film such as SiO₂, the ratio of flow rate of the Mn-containing source gas to the Cu-containing source gas may be increased in the initial stage of film formation to form the alloy film of which components are rich in Mn.

Further, the supply period t1 of the Mn-containing source gas is about 10 to 15 sec, the supply period t2 of the Cu-containing source gas is about 10 sec, the supply period t3 of the H₂ gas is about 10 sec, and the intermittent period T1 is about 20 to 120 sec. Herein, because Cu has weak adhesion to an insulation film such as SiO₂, as described above, the supply period t1 of the Mn-containing source gas may be slightly longer than the supply period t2 of the Cu-containing source gas in the initial stage of film formation. For example, the supply period t1 may be 15 sec (as indicated by a dotted line 121 in FIG. 4A). That is, a process recipe can be made so that the ratio of the supply of the Mn-containing source gas to that of the Cu-containing source gas changes depending on the lapse of film formation time or the thickness of a deposition film. Accordingly, it is also possible to gradually change the components of the CuMn alloy film from a Mn-rich state to a Cu-rich state. Accordingly, the adhesion between the insulating layer 1 and the seeding film 6 and between the seeding film 6 and the Cu film 8 can be increased, thus preventing film peeling off and the like during film formation.

In the case shown in FIG. 4A, the Mn-containing source gas and the Cu-containing gas are supplied in a synchronized manner, but the third film forming method is an ADL method shown in FIG. 4B. In the third method, the two gases are alternately and repeatedly supplied while leaving an intermittent period, and during the intermittent period, H₂ gas is supplied. In this case, the period of one cycle is two-fold longer than that of the one cycle shown in FIG. 4A. Further, the formed seeding film 6 is an alloy film formed of an Mn film having a very small film thickness of about 0.2-0.3 nm and a Cu film having a very small film thickness of about 0.2-0.3 nm, which are alternately laminated. As shown in FIG. 4B, the first step is preferably carried out so that the Mn-containing source gas is supplied before the supply of the Cu-containing source gas in consideration of adhesion and barrier properties between the seeding film 6 and the insulating layer 1. Further, because two laminated films are very thin, Mn and Cu diffuse toward each other to form an alloy.

In film formation by the ALD method, the film is sufficiently attached even to the inner wall of a fine recess compared to film formation by the CVD method, and thus step coverage can be further improved. Particularly, as the dimension of a recess becomes finer, the ALD method is more effective.

Then, when a Cu film is formed as a metal film 8 shown in FIG. 2C and S2 in FIG. 3A, the Cu-containing source gas and the H₂ gas may be supplied simultaneously, and the metal film 8 formed of a Cu film may be formed by the CVD method. Alternatively, the Cu-containing source gas and the H₂ gas may be supplied alternately and repeatedly in the manner as shown in FIGS. 4A and 4B.

Alternatively, the metal film 8 formed of a Cu film may be formed by a simple thermal decomposition reaction without supplying H₂ gas.

In this case, the process conditions (including those in CVD treatment) are as follows: the processing temperature in a range from about 70 to 450° C., the processing pressure in a range from about 1 Pa to 13 kPa, the flow rate of Cu-containing source gas in a range from about 1 to 100 sccm, and the flow rate of H₂ gas is in a range from about 5 to 500 sccm.

Further, the metal film 8 formed of a Cu film may be formed by using the PVD method (sputtering or vapor deposition) in the prior art or plating method instead of the CVD method or ALD method, thus filling the recess.

Particularly, in the case of the CVD or ALD method, a thin film is easy to deposit on the inner wall of a fine recess compared to the plating method, and thus, even when a recess becomes finer, the filling of the recess can be achieved without causing voids and the like in the recess. Then, when an annealing process shown in FIG. 2D and S3 in FIG. 3A is carried out, the wafer W which has undergone the filling process is heated to a specific processing temperature, for example, about 100-450° C., whereby a barrier layer 112 formed of a MnSixOy film is securely formed in a self-aligned manner at the interface between the seeding film 6 and the underlying insulating layer 1 formed of a SiO₂ film. Further, in the annealing process, oxygen from an oxygen supply unit 76a may be supplied into the processing chamber 14, and the partial pressure of oxygen may be controlled.

The annealing process aims to secure the formation of the barrier layer 112, and thus if the seeding film forming process or Cu-film forming process as the pre-process, is carried out at a sufficiently high temperature, for example, a high processing temperature of 150° C., the annealing process may be unnecessary, because the barrier layer 112 has already been formed to a sufficient thickness. However, if the plating process is carried out in S2 in FIG. 3A, the annealing process will of course be carried out.

Herein, the seeding film forming process, the Cu film forming process by the CVD or ALD method, and the annealing process may all be continuously carried out in the same processing apparatus 12.

As described above, in the processing chamber 14 which can be vacuum-exhausted, the thin film is formed by heat treatment by using the Cu-containing source gas, the transition metal Mn-containing source gas and the H₂ gas as reduction gas, and thus even a fine recess 2 can be filled with high step coverage. Further, continuous processes can be carried out in the same processing apparatus 12, and thus apparatus expenses can be greatly reduced.

In addition, because continuous processes can be carried in the same processing apparatus insitu, the formation of unnecessary metal oxide films can be suppressed and, as a result, filling properties can be improved and, at the same time, contact resistance can be prevented from being increased. Therefore, it is possible to improve the reliability of semiconductor devices and the yield of semiconductor devices.

In addition, a process for forming a barrier layer formed of a Ta or TaN film in the prior art, is unnecessary, and thus throughput can be improved even more.

Furthermore, if the CuMn alloy film is used as the seeding film 6, the adhesion thereof to the metal film 8 formed thereon can be increased, because the filling material Cu is partially contained in the seeding film 6. Hereinafter, the matter of changing the ratio between the Cu and Mn components in the CuMn film will be described in detail.

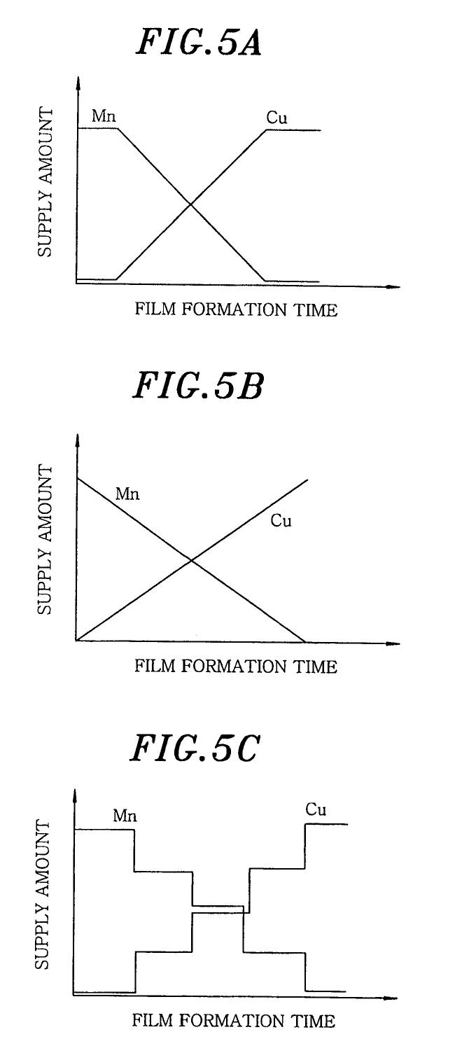

FIG. 5 graphically shows examples of the changes in the supply amounts of the Mn-containing source gas and the Cu-containing source gas as a lapse of film formation time (in the heat treatment). Also, the graphs show only the tendency of the changes in the supply amounts, but do not show the absolute values of the amounts supplied.

Herein, as described above, the amount of the supplied copper-containing source gas and/or transition metal-containing source gas is changed during the heat treatment in order to change the composition ratio between copper (Cu) and the transition metal, for example Mn, in the thin film, in the film thickness direction. Specifically, the supply amount of each source gas is controlled so that the composition ratio of the transition metal in the CuMn thin film is high in the lower layer side of the thin film and becomes smaller toward the upper layer side. That is, as shown in FIG. 5A, in the initial stage of film formation, the Mn-containing source gas is supplied in a high flow rate, and after a while, the flow rate is decreased gradually, for example, linearly with the lapse of film formation time, and finally becomes almost zero.

In comparison with this, in the initial stage of film formation, the Cu-containing source gas is not substantially supplied for a while, so that a pure Mn metal film is formed. Then the flow rate of the Cu-containing source gas is increased, for example, linearly with the lapse of film formation time to correspond to the decrease in the Mn-containing source gas. In the final stage, while the amount of the Mn-containing source gas supplied is maintained in almost zero, the flow rate of the Cu-containing source gas is maximized, so that a pure Cu metal film is formed.

In this case, the thin film is made of a pure Mn metal film in the initial stage of film formation, and then made of a CuMn alloy, while a Mn-rich state is continued. Then, it is converted to a Cu-rich state, and finally formed of a pure Cu metal film.

In FIG. 5B, in the initial stage of film formation, the amount of the Mn-containing source gas supplied is gradually decreased from a specific supply amount, whereas the amount of Cu-containing source gas supplied is gradually increased from a supply amount of zero. In this case, the thin film is made of a CuMn film entirely in the thickness direction thereof, and a pure Mn metal film or a pure Cu metal film is not formed, as shown in FIG. 5A. Further, in FIGS. 5A and 5B, the linear increase or decrease in the supply amount of each source gas is shown, but the amount of each source gas supplied may also be regulated to show a curved increase or decrease rather than the linear increase or decrease.

In the case of FIGS. 5A and 5B, the composition ratio between Cu and Mn in the CuMn alloy film portion continuously changes from a Mn-rich state to a Cu-rich state toward the upper side from the lower side of the film. As shown in FIG. 5C, the Mn-containing source gas is decreased stepwise, and in relation to this, the Cu-containing source gas is increased stepwise. In this case, the composition ratio between Cu and Mn in the CuMn alloy film changes in a stepwise shape. Further, the number of the steps is not limited to any particular number.

In the cases shown in FIGS. 5A to 5C, the lower layer of the film is made of a pure Mn metal film or a Mn-rich CuMn alloy, and the upper layer is made of a pure Cu metal film or a Cu-rich CuMn alloy, and thus, as described above, the adhesion to the Cu film 8 and the underlying film SiO₂ can be further improved.

In the above embodiment, the formation of the CuMn alloy film as the seeding film 6 has been described by way of example (S1 in 3A), but, as described above, a Mn film (S1-1 in FIG. 3B) may be formed as the seeding film. The formation of the Mn film can be performed by using any one of a method of simultaneously supplying the Mn-containing source gas and the H₂ gas as reduction gas and forming the film by the CVD method, and a method of introducing the Mn-containing source gas and the H₂ gas alternately and repeatedly as shown in FIG. 4C and forming the film by the ALD method. In this case, the process conditions, for example, the processing pressure, the processing temperature, the flow rate of each gas and the like are same as those described by referring to FIG. 4A and FIG. 4B. Further, S2 and S3 in FIG. 3B are the same steps as S2 and S3 in FIG. 3A, respectively. In this case, if the barrier layer 112 is sufficiently formed in the previous process, the annealing process of S3 in FIG. 3B can be omitted. Furthermore, even when the Cu film is deposited on the Mn film, the adhesion between these metals can be improved by processing these films insitu.

When the Mn film is formed as the seeding film 6, the Cu wiring layer 8 formed above the seeding film 6 is connected to the underlying Cu wiring layer 3 via the Mn film having a resistance value higher than that of a Cu film at the bottom of the recess. However, because this seeding film is a lot thinner than the Mn film formed in the prior sputtering method, a majority of the Mn element diffuses into the Cu wiring layer 3 and the Cu wiring layer 8 by annealing or the like, and thus is not present as a Mn layer. Accordingly, the contact resistance of the seeding film 6 does not increase.

Also, the amount of Mn metal contained in the CuMn thin film (including cases having a pure Mn metal film or a pure Cu metal film) or in the Mn film has an optimal value which is in a range of 0.7 to 2.6 nm when converted into the film thickness of pure Mn metal. The thin film is preferably formed so that the amount of Mn metal is in the range of the values calculated in terms of the Mn metal film thickness. That is, in the annealing process, Mn reacts as described above to form a MnSixOy film, surplus Mn diffuses into the Cu film to some degree and is discharged to the surface, but if Mn is included in the film in an excessive amount, the Mn component which has not been discharged remains in the Cu film filled in the recess, and the remaining Mn component results in an increase in the resistance value of the Cu wiring, thus deteriorating the reliability of the wiring.

In this case, by setting the content of Mn in the thin film in a range of 0.7 to 2.6 nm in terms of the film thickness of pure Mn metal as described above, a necessary and sufficient amount of Mn can be maintained in the barrier layer that is the interface between the Cu wiring and the insulating layer. If the content of Mn is smaller than a thickness of 0.7 nm, a barrier layer of good characteristics cannot be made, and if the Mn content is larger than 2.6 nm, a surplus Mn component remains in the Cu wiring as described above and deteriorates the characteristics of the Cu wiring.

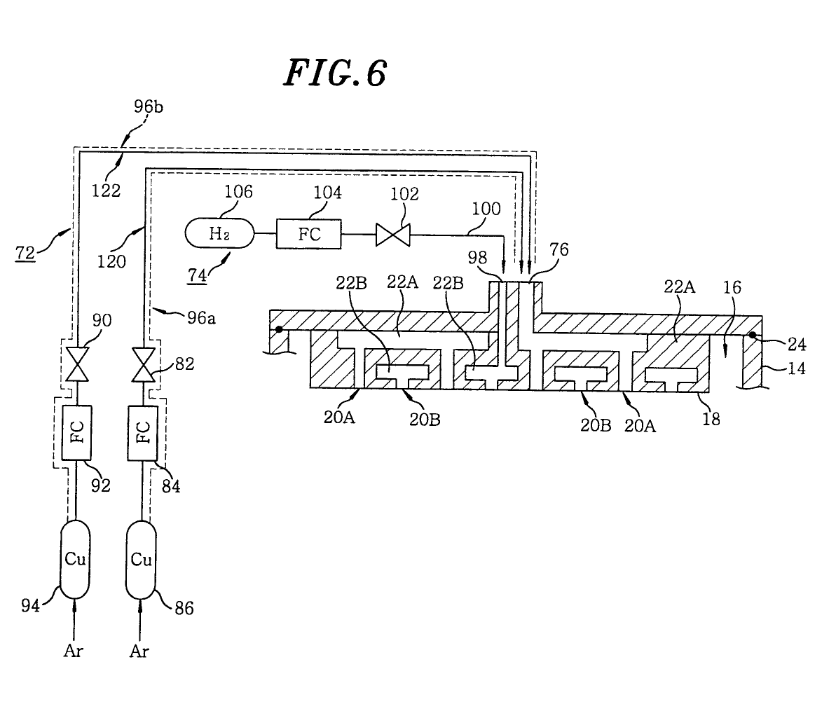

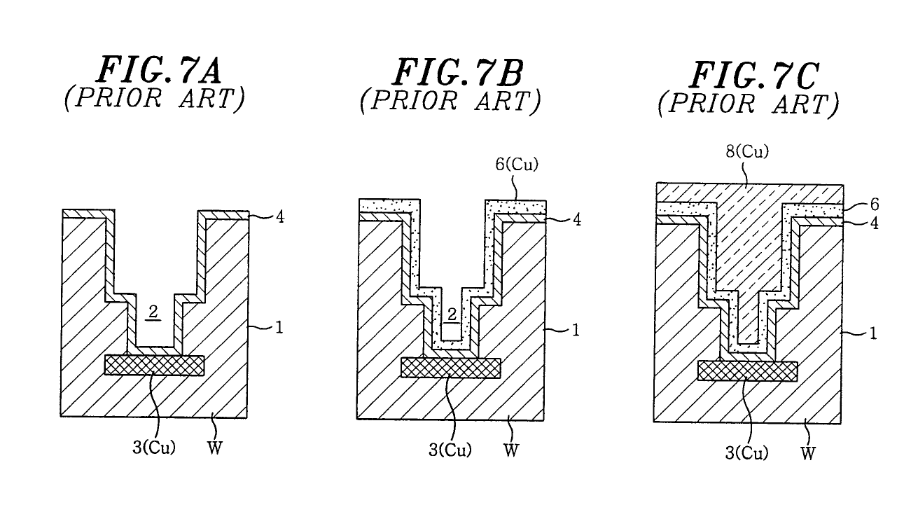

In the apparatus shown in FIG. 1, the two source gas lines of the source material supply unit 72 join together at halfway, but the present invention is not limited thereto, and they may be distinct and separated. FIG. 6 is a partial configuration view showing a modified embodiment of the source gas supply unit in the film forming apparatus. In FIG. 6, the shower head 16 and the source material supply unit 72 connected thereto are shown, and the same elements as those in FIG. 1 are indicated by the same reference numerals.

In FIG. 6, source gas lines 120 and 122 extend from a first source material supply source 86 containing Mn and a second source material supply containing Cu, respectively. Also, the source gas lines 120 and 122 are commonly connected to a gas inlet 76 in the shower head 16 without joining together halfway, so that the source gases are introduced into the shower head 16 without being mixed with each other during the delivery thereof.

In this case, the source gas lines 120 and 122 are wound with line heating unit 96a and 96b made of, for example, tape heaters, whereby they are heated to prevent the source gases flowing therethrough from being re-liquefied. In this case, each of the source gas lines 120 and 122 is heated to thereby be maintained at an optimal temperature corresponding to the source gas flowing therethrough. Specifically, if (MeCp)₂Mn is used as the source material, the source gas line 96a is heated to a temperature in range of, for example, from 70 to 90° C., and if Cu(hfac)TMVS is used as the source material, the source gas line 96b is set to a temperature in a range of, for example, from 55 to 70° C. In this case, the same effects as described previously can be obtained.

Further, the organometallic material is not limited to those described above, and any organometallic material may be used, as long as it is formed of a transition metal, carbon (C) and hydrogen (H). As the organometallic material, M(R-Cp)x (x: natural number) or M(R-Cp)x(CO)y (x and y: natural numbers) may also be used. Herein, M represents transition metal, R represents an alkyl group and is one selected from the group formed of H, CH₃, C₂H₅, C₃H₇ and C₄H₉, Cp is cyclopentadienyl group (C₅H₄), and CO is a carbonyl group.

In addition, as the Mn-containing organometallic material, at least one material selected from the group formed of Cp₂Mn[═Mn(C₅H₅)₂], (MeCp)₂Mn[═Mn(CH₃C₅H₄)₂], (EtCp)₂Mn[═Mn(C₂H₅C₅H₄)₂], (i-PrCp)₂Mn[═Mn (C₃H₇C₅H₄)₂], MeCpMn(CO)₃[═(CH₃C₅H₄)Mn(CO)₃], (t-BuCP)₂Mn[═Mn(C₄H₉C₅H₄)₂], CH₃Mn(CO)₅, Mn(DPM)₃[═Mn(C₁₁H₁₉O₂)₃], Mn(DMPD)(EtCp)[═Mn(C₇H₁₁C₂H₅C₅H₄)], Mn(acac)₂[═Mn(C₅H₇O₂)₂], Mn(DPM)₂[═Mn(C₁₁H₁₉O₂)₂], Mn(acac)₃[═Mn(C₅H₇O₂)₃] and Mn(hfac)₂[═Mn(C₅HF₆O₂)₃] may be used. In addition to the organometallic material, metal complex materials may also be used.

Further, while the use of SiO₂ as the underlying insulating layer 1 has been described herein by way of example, the present invention is not limited thereto, and a SiOC film, a SiCOH or the like, i.e. low-k (low dielectric) material which is used as interlayer insulating layers, may be used. Specifically, as the underlying film, one selected from the group formed of a SiO₂ film (including a thermal oxide film and a plasma TEOS film), a SiOC film, a SiCOH film, a SiCN film, a porous silica film, a porous methylsilsesquioxane film, a polyarylene film, a SiLK (registered trademark name) film, a fluorocarbon film, and laminated films thereof.

Moreover, although H₂ gas has been used herein as the reduction gas, H₂O or a vaporized organic solvent, for example, ethanol, isopropyl alcohol, acetone, hexane, octane or butyl acetate, may also be used.

Furthermore, although the use of Mn as the transition metal has been described by way of example, the present invention is not limited thereto, and other transition metals, for example, one or more metals selected from the group formed of Mn, Nb, Zr, Cr, V, Y, Pd, Ni, Pt, Rh, Tc, Al, Mg, Sn, Ge, Ti and Re, may be used.

In addition, the film forming apparatus described herein is merely one example. For example, a heating lamp such as a halogen lamp may be used instead of the resistance heater as the heating unit, and the processing apparatus may be not only of the sheet-type, but also of the batch-type. Furthermore, the scope of the present invention is not limited to film formation by heat treatment. For example, using the shower head 16 as an upper electrode and the mounting table 44 as a lower electrode, a high-frequency power may, if necessary, be applied between the electrodes to form a plasma, and an assist by the plasma may also be applied during film formation.

In addition, although the semiconductor wafer has been described herein as the substrate by way of example, the scope of the present invention is not limited thereto, and the present invention may also be applied to a glass substrate, an LCD substrates, a ceramic substrate and the like.

What is claimed is:

1. A film forming method comprising:
loading a substrate to be processed into a vacuum-evacuable processing chamber; and
supplying at least a transition metal-containing source gas and a reduction gas into the processing chamber, while heating the substrate, thereby forming a thin film on a surface of the substrate by heat treatment.

2. The method of claim 1, wherein a copper-containing source gas, the transition metal-containing source gas and the reduction gas are supplied into the processing chamber, while the substrate is heated, thereby forming a thin film on the substrate surface by heat treatment.

3. The method of claim 1, wherein the heat treatment is a CVD (chemical vapor deposition) method.

4. The film forming method of claim 1, wherein the heat treatment is an ALD (atomic layer deposition) method in which a film formation is performed by alternately and repeatedly supplying the source gases and the reduction gas.

5. The film forming method of claim 2, wherein the heat treatment is performed by alternately and repeatedly supplying the two source gases with an intermittent period therebetween and supplying the reduction gas during the intermittent period.

6. The film forming method of claim 1, wherein a filling of a recess formed in the substrate is performed by depositing a copper film by a CVD method on the substrate formed with the thin film thereon.

7. The film forming method of claim 6, wherein the filling is performed in the processing chamber in which the thin film has been formed.

8. The film forming method of claim 6, wherein an annealing process is performed on the substrate, after the filling is performed.

9. The film forming method of claim 8, wherein the annealing process is performed in the processing chamber in which the thin film has been formed.

10. The film forming method of claim 1, wherein a filling of a recess in the substrate is performed by depositing a copper film by a plating method on the substrate formed with the thin film thereon.

11. The film forming method of claim 10, wherein an annealing process is performed on the substrate, after the filling of the recess in the substrate is performed.

12. The film forming method of claim 2, wherein the amount of the copper-containing source gas and/or the transition metal-containing source gas supplied is changed during the heat treatment in order to change a composition ratio between copper and transition metal in the thin film, in the thickness direction of the thin film.

13. The film forming method of claim 12, wherein the amount of each of the source gases supplied is controlled so that the composition ratio of the transition metal in the thin film is high at the lower layer side of the thin film and decreases toward the upper layer side of the thin film.

14. The film forming method of claim 1, wherein an amount of the transition metal contained in the thin film is in a range from 0.7 to 2.6 nm, when converted into a film thickness of the pure transition metal contained in the thin film.

15. The film forming method of claim 1, wherein the substrate surface is an underlying film of the thin film, the underlying film being made of at least one film selected from a group formed of a SiO₂ film, a SiOC film, a SiCOH film, a SiCN film, a porous silica film, a porous methylsilsesquioxane film, a polyarylene film, a SiLK (registered trademark name) film and a fluorocarbon film.

16. The film forming method of claim 1, wherein a source material of the transition metal-containing source gas is formed of an organometallic material or a metal complex material.

17. The film forming method of claim 16, wherein the organometallic material is M(R-Cp)x, x being a natural number, wherein M represents a transition metal, R represents an alkyl group and is one selected from the group formed of H, CH₃, C₂H₅, C₃H₇ and C₄H₉, and Cp is a cyclopentadienyl group (C₅H₄) .

18. The film forming method of claim 16, wherein the organometallic material is M(R-Cp)x(CO)y, x and y being natural numbers, wherein M represents a transition metal, R represents an alkyl group and is one selected from the group formed of H, CH₃, C₂H₅, C₃H₇ and C₄H₉, Cp is a cyclopentadienyl group (C₅H₄), and CO is a carbonyl group.

19. The film forming method of claim 16, wherein the organometallic metal formed of a transition metal, C and H.

20. The film forming method of claim 1, wherein the transition metal is at least one selected from a group formed of Mn, Nb, Zr, Cr, V, Y, Pd, Ni, Pt, Rh, Tc, Al, Mg, Sn, Ge, Ti and Re.

21. The film forming method of claim 16, wherein the transition metal is formed of manganese (Mn), and the corresponding organometallic material containing manganese is at least one material selected from a group formed of Cp₂Mn[═Mn(C₅H₅)₂], (MeCp)₂Mn[═Mn (CH₃C₅H₄)₂], (EtCp)₂Mn[═Mn(C₂H₅C₅H₄)₂], (i-PrCp)₂Mn[═Mn(C₃H₇C₅H₄)₂], MeCpMn(CO)₃[═(CH₃C₅H₄)Mn(CO)₃], (t-BuCp)₂Mn[═Mn(C₄H₉C₅H₄)₂], CH₃Mn(CO)₅, Mn(DPM)₃[═Mn(C₁₁H₁₉O₂)₃], Mn(DMPD)(EtCp)[═Mn(C₇H₁₁C₂H₅C₅H₄)], Mn(acac)₂[═Mn(C₅H₇O₂)₂], Mn(DPM)₂[═Mn(C₁₁H₁₉O₂)₂], Mn(acac)₃[═Mn(C₅H₇O₂)₃] and Mn(hfac)₂[═Mn(C₅HF₆O₂)₃].

22. The film forming method as of claim 1, wherein a plasma is used in the heat treatment.

23. The film forming method of claim 1, wherein the source gases and the reduction gas are mixed with each other in the processing chamber.

24. The film forming method of claim 1, wherein the reduction gas is H₂ gas.

25. A film forming apparatus for forming a transition metal-containing thin film on a surface of a substrate to be processed by heat treatment, the apparatus comprising:
a vacuum-evacuable processing chamber;
a mounting table structure provided in the processing chamber for mounting thereon the substrate;
a heating unit for heating the substrate;
a gas introducing unit for introducing a gas into the processing chamber;
a source gas supply unit for supplying one or more source gases into the gas introducing unit; and
a reduction gas supply unit for supplying a reduction gas into the gas introducing unit.

26. The film forming apparatus of claim 25, wherein the number of the source gases is greater than one and the source gas supply unit has different source material branch lines provided respectively for the source gases, wherein the source gas branch lines join together before reaching the gas introducing unit.

27. The film forming apparatus of claim 25, wherein the number of the source gases is greater than one, and the source gas supply unit has different source material branch lines respectively provided for the source gases, the source gas branch lines being commonly connected to the gas introducing unit without joining together.

28. The film forming apparatus of claim 26 or 27, wherein the source gas branch lines are provided with a line heating unit for heating in order to prevent liquefaction of the source gases flowing through the respective source gas branch lines.

29. The film forming apparatus of claim 25, wherein the source gas at least includes a transition metal-containing source gas.

30. The film forming apparatus of claim 29, wherein the source gas includes a copper-containing source gas and a transition metal-containing source gas.

31. The film forming apparatus of claim 25, wherein the reduction gas is H₂ gas.

32. A computer executable-program which is used in a film forming apparatus to execute a film forming method in a computer, the film forming method comprising:
loading a substrate to be processed into a vacuum-evacuable processing chamber; and
supplying at least a transition metal-containing source gas and a reduction gas into the processing chamber, while heating the substrate, thereby forming a thin film on a surface of the substrate by heat treatment.

33. A computer executable-program for executing a method of forming a transition metal-containing thin film on a substrate to be processed by heat treatment by using a film forming apparatus, the film forming apparatus comprising:
a vacuum-evacuable processing chamber;
a mounting table structure provided in the processing chamber for mounting thereon the substrate;
a heating unit for heating the substrate;
a gas introducing unit for introducing a gas into the processing chamber;
a source gas supply unit for supplying one or more source gases into the gas introducing unit;
a reduction gas supply unit for supplying a reduction gas into the gas introducing unit; and
a control unit for controlling all the units of the apparatus,
wherein the film forming method comprises:
loading the substrate into the vacuum-evacuable processing chamber; and
supplying at least a transition metal-containing source gas and the reduction gas into the processing chamber, while heating the substrate, thereby forming a thin film on a surface of the substrate by the heat treatment.

34. The computer executable-program of claim 33, wherein the source gases include a copper-containing source gas and the transition metal-containing source gas.

35. A computer-readable storage medium storing therein a computer-executable program which is used in a film forming apparatus to execute a film forming method in a computer, the film forming method comprising:
loading a substrate to be processed into a vacuum-evacuable processing chamber; and
supplying at least a transition metal-containing source gas and a reduction gas into the processing chamber, while heating the substrate, thereby forming a thin film on a surface of the substrate by heat treatment.

36. A computer-readable storage medium storing a computer-executable program for executing a method of forming a transition metal-containing thin film on a substrate by heat treatment by using a film forming apparatus, the film forming apparatus comprising:
a vacuum-evacuable processing chamber;
a mounting table structure provided in the processing chamber for mounting thereon the substrate;
a heating unit for heating the substrate;
a gas introducing unit for introducing a gas into the processing chamber;
a source gas supply unit for supplying one or more source gases into the gas introducing unit;
a reduction gas supply unit for supplying a reduction gas into the gas introducing unit; and
a control unit for controlling all the units of the apparatus,
wherein the film forming method comprises:
loading the substrate into the vacuum-evacuable processing chamber; and
supplying at least a transition metal-containing source gas and the reduction gas into the processing chamber, while heating the substrate, thereby forming a thin film on a surface of the substrate by the heat treatment.

37. The computer-readable storage medium of claim 36, wherein the source gases include a copper-containing source gas and the transition metal-containing source gas.
